(19) United States
(12) Patent Application Publication
(10) Pub. No.: US 2026/0072345 A1
(43) Pub. Date: Mar. 12, 2026

(54) METHOD OF INSPECTING A RISK OF PRINTING DEFECT PATTERN IN PHOTOLITHOGRAPHY PROCESS

(71) Applicant: Powerchip Semiconductor Manufacturing Corporation, HSINCHU (TW)

(72) Inventors: Chih-Wei Chiu, HSINCHU (TW); Pei-Shan Shih, HSINCHU (TW)

(73) Assignee: Powerchip Semiconductor Manufacturing Corporation, HSINCHU (TW)

(21) Appl. No.: 18/955,918

(22) Filed: Nov. 21, 2024

(30) Foreign Application Priority Data
Sep. 6, 2024 (TW) 113133795

(51) Int. Cl. G03F 1/84; G03F 7/00

(52) U.S. Cl. CPC G03F 1/84; G03F 7/70666; G03F 7/706837; G03F 7/706839

(57) ABSTRACT

A method of inspecting a risk of printing defective pattern in photolithography process, including generating an intensity curve of a photomask pattern in aerial image simulation, wherein the intensity curve is provided with a primary trough and a secondary troughs adjacent to the primary trough, the aerial image simulation is provided with a threshold intensity intersecting one of the secondary troughs to define an intensity region, partitioning the intensity region into multiple rectangular fragments, summing up areas of the rectangular fragments to obtain a total area, and determining the photomask pattern having no risk of forming defective pattern if the total area is smaller than a spec value and determining the photomask pattern having risk of forming defective pattern if the total area is larger than the spec value.

### BACKGROUND OF THE INVENTION

### 1. Field of the Invention

The present invention generally relates to a method of inspecting patterns formed in photolithography process, and more specifically, to a method of inspecting sidelobe patterns and sub-resolution assistant feature (SRAF) printing in photolithography process.

### 2. Description of the Prior Art

Photolithography technology is a technology that can apply a desired pattern on a target part or a target layer on a substrate, and it can be used in the manufacturing of integrated circuits (IC). In this application, a patterning device (may also be referred as a photomask or mask) is used to generate circuit patterns corresponding to individual levels of IC, i.e. 2D layout patterns, and these circuit patterns can be imaged on a target part (including partial die, one or more dies) of a photosensitive material layer (ex. photoresist) on the substrate (ex. a wafer). In this way, by using the photosensitive material layer with these imaged circuit patterns as a mask in semiconductor process, the desired IC pattern can be produced in a target level on the substrate.

As semiconductor technology evolves into deep sub-micron field, existing photolithography technology has reached its resolution limit due to the factors such as reduced depth of field (DOF), difficulty in designing and manufacturing projection systems. In order to deal with this problem, the industry has been working hard to develop various resolution enhancement technologies. Attenuated phase-shift mask (Att-PSM) is one of these technologies, which is widely used in nowadays semiconductor manufacture for fine geometric patterns, capable of achieving higher process tolerance and pattern resolution than traditional binary photomask. The principle of attenuated phase-shift mask is to replace the opaque parts of traditional photomask with a half-tone film, so that the destructive interference between the diffraction waves generated in the process may help pattern imaging.

Nevertheless, a major problem of attenuated phase-shift masks is that unwanted sidelobe patterns and sub-resolution assistant features (SRAF) may be printed out. The cause of these print-outs lies that constructive interference between adjacent feature patterns (closely spaced on the order of the wavelength of radiation light) in the photmask pattern may render the intensity of non-feature patterns to exceed a threshold, thus unnecessary patterns adjacent to the main patterns may be formed in the photolithography process, especially in dense areas with fine-pitch patterns, such as the dense areas with line patterns and contact hole patterns in advanced semiconductor process. Due to the formation of unnecessary patterns, the problem of sidelobe and SRAF printing will seriously affect the process yield. Therefore, how to inspect the sidelobe and SRAF printing and determine the risk of their formation is an important part in the layout design and simulation of ICs.

### SUMMARY OF THE INVENTION

In the light of the problem of sidelobe and SRAF printing in prior art, the present invention hereby proposes a novel method of inspecting sidelobe and SRAF printing, which is characterized by determining the risk of sidelobe and SRAF printing through intensity region instead of intensity ratio, which has higher accuracy and discrimination than conventional inspecting methods.

One aspect of the present invention is to provide a method of inspecting a risk of printing defective pattern in photolithography process, including steps of: providing a photomask pattern; generating an intensity curve of the photomask pattern in a first direction in an aerial image simulation, wherein the aerial image simulation has a threshold intensity, and the intensity curve is provided with a primary trough and a secondary trough adjacent to the primary trough, and the primary trough is lower than the secondary trough, and the threshold intensity is higher than the secondary trough, so that the threshold intensity intersects with the secondary trough to define an intensity region; partitioning the intensity region into a plurality of rectangular fragments arranged in the first direction; adding up areas of the rectangular fragments to obtain a total area; and when the total area is less than a specification value, it is determined that the photomask pattern has no risk of printing defective pattern in the photolithography process, and when the total area is greater than the specification value, it is determined that the photomask pattern has a risk of printing defective pattern in the photolithography process.

Another aspect of the present invention is to provide a method of inspecting a risk of printing defective pattern in photolithography process, including steps of: providing a photomask pattern; generating an intensity curve of the photomask pattern in a first direction in an aerial image simulation, wherein the aerial image simulation has a threshold intensity, and the intensity curve is provided with a primary crest and a secondary crest adjacent to the primary crest, and the primary crest is higher than the secondary crest, and the threshold intensity is lower than the secondary crest, so that the threshold intensity intersects with the secondary crest to define an intensity region; partitioning the intensity region into a plurality of rectangular fragments arranged in the first direction; adding up areas of the rectangular fragments to obtain a total area; and when the total area is less than a specification value, it is determined that the photomask pattern has no risk of printing defective pattern in the photolithography process, and when the total area is greater than the specification value, it is determined that the photomask pattern has a risk of printing defective pattern in the photolithography process.

Still another aspect of the present invention is to provide a computer program product with computer-executable instructions that are executed by a computer to perform a method of inspecting a risk of printing defective pattern in photolithography process, the method includes steps of: providing a photomask pattern; generating an intensity curve of the photomask pattern in a first direction in an aerial image simulation, wherein the aerial image simulation has a threshold intensity, and the intensity curve is provided with a primary trough and a secondary trough adjacent to the primary trough, and the primary trough is lower than the secondary trough, and the threshold intensity is higher than the secondary trough, so that the threshold intensity intersects with the secondary trough to define an intensity region; partitioning the intensity region into a plurality of rectangular fragments arranged in the first direction; adding up areas of the rectangular fragments to obtain a total area; and when the total area is less than a specification value, it is determined that the photomask pattern has no risk of printing defective pattern in the photolithography process, and when the total area is greater than the specification value, it is determined that the photomask pattern has a risk of printing defective pattern in the photolithography process.

Still another aspect of the present invention is to provide a computer program product with computer-executable instructions that are executed by a computer to perform a method of inspecting a risk of printing defective pattern in photolithography process, the method includes steps of: providing a photomask pattern; generating an intensity curve of the photomask pattern in a first direction in an aerial image simulation, wherein the aerial image simulation has a threshold intensity, and the intensity curve is provided with a primary crest and a secondary crest adjacent to the primary crest, and the primary crest is higher than the secondary crest, and the threshold intensity is lower than the secondary crest, so that the threshold intensity intersects with the secondary crest to define an intensity region; partitioning the intensity region into a plurality of rectangular fragments arranged in the first direction; adding up areas of the rectangular fragments to obtain a total area; and when the total area is less than a specification value, it is determined that the photomask pattern has no risk of printing defective pattern in the photolithography process, and when the total area is greater than the specification value, it is determined that the photomask pattern has a risk of printing defective pattern in the photolithography process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an intensity graph of a photomask pattern in accordance with one embodiment of the present invention;

FIG. 2 is an enlarged graph of an intensity region in accordance with one embodiment of the present invention;

FIG. 3 is an intensity graph of a photomask pattern in accordance with another embodiment of the present invention;

FIG. 4 is a chart used to determine the risk of SRAF printing based on intensity ratio in conventional skill;

FIG. 5 is a chart used to determine the risk of SRAF printing based on intensity region in accordance with one embodiment of the present invention; and

FIG. 6 is a flowchart of the method for inspecting sidelobe and SRAF printing in photolithography process in accordance with one embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

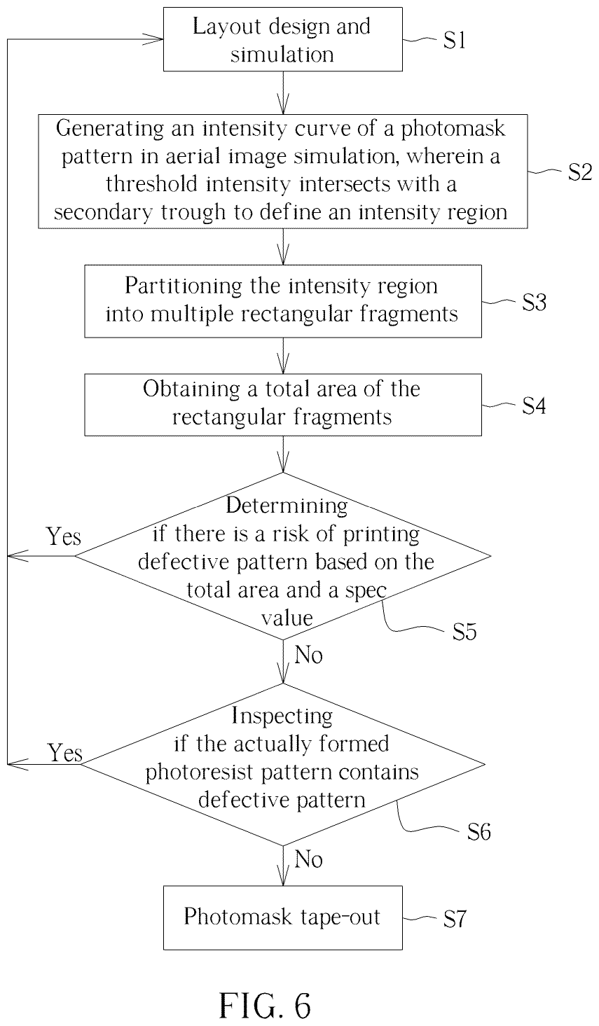

First, please refer to FIG. 6, which is a flowchart of the method of inspecting sidelobe and SRAF printing in photolithography process in accordance with one embodiment of the present invention. The following embodiments will describe the principle and method of inspecting sidelobe and SRAF printing in photolithography process of the present invention based on the steps shown in the figure. It should be noted that the method proposed by the present invention can be used to inspect whether a designed layout pattern has a risk of printing sidelobe and SRAF patterns in aerial image simulation before the production of photomask. It can also, but not limited, be used in ADI inspection (after development inspection) after the photomask is produced, to inspect whether the formed photoresist pattern has a risk of printing sidelobe and SRAF patterns.

Furthermore, one or more embodiments of the present invention are a method of checking IC designs in the form of digital computer files. These types of files will depict a plurality of features and their positions on a 2D layout level. The operation of this checking usually includes determining whether the IC design follows the design rules related to manufacturing technology (for example, determining a predetermined spacing relation between feature patterns) or determining whether the IC design follows electrical rules (for example, detecting potential misalignment or if the safe operating area (SOA) is exceed in IC layout levels). In the case of the present invention, it is to determine whether the feature pattern has risks of sidelobe or SRAF printing in a specific specification of photolithography process. Preferably, one or more of these embodiments in the present invention are implemented on a computer-implemented program for checking design rule or electrical rule or on a circuit simulation program, which may include the use of a general-purpose computer that can execute the computer-implemented method of present invention, in which the user can input instructions for executing the computer-implemented method of present invention through user interfaces including a monitor, a keyboard, a mouse and other devices. The processor will read computer-readable codes and data from dynamic random access memory (DRAM) and performs calculations and processing on them. A high-capacity storage device, such as a disk drive, can provide the program code and data related to the computer-implemented method of the present invention and load them into DRAM. Input/output devices may provide data connections to transmit data to other device, such as networks, modems, printers, etc. However, it should be understood that for those of ordinarily skilled in the art, some embodiments of the invention may be implemented or practiced without certain or all of these specific details. In other instances, such conventional operation and process will not be described in detail to avoid obscuring the focus of the present invention.

First, in step S1, an IC layout design is performed to generate a 2D layout required for an IC. The steps involved may include specification definition and functional design of front-end system level, and logic design and circuit design of register-transfer level (RTL), and physical design of back-end level, etc. These steps may be implemented through an electronic design automation (EDA) platform installed on a computer architecture, and include the use of various circuit simulation tools, layout tools or inspection tools based on device models to simulate and test the designed layout circuit, thereby producing a correct binary GDSII format file for semiconductor manufacturers to manufacture photomasks or semiconductor devices. The inspection of sidelobe or SRAF patterns of the present invention can also be included in the aforementioned simulation and inspection. Since the steps of IC design above are conventional skills and not the focus of the present invention, their detailed description will be herein omitted, and only relevant technologies of the present invention will be described in detail. This step S1 will at least proceed to the stage of generating 2D layouts for each layout level in physical design.

Next, in step S2, an intensity curve of a feature pattern is generated in an aerial image simulation. This aerial image simulation can be one of the simulation steps in the aforementioned stage of IC layout design. The so-called aerial image is an intensity distribution of the electric field of a feature pattern projected on a substrate plane. The feature pattern may be a feature pattern in the 2D layout of a certain circuit level, such as line patterns, trench patterns or contact hole patterns, etc., which will be formed on a photomask as a patterning device for subsequent semiconductor process after the circuit design stage is completed. These feature patterns will be referred hereinafter as photomask patterns. Since in actual photolithography process, the pattern on photomask is developed on a photosensitive material by emitting radiation light from photolithography equipment and passing through transparent regions on the photomask. When the feature size of the photomask pattern is on the order of the wavelength of radiation light, diffraction will occur to render the electric field intensity in a waveform distribution, especially when an attenuated phase-shift mask (Att-PSM) is used.

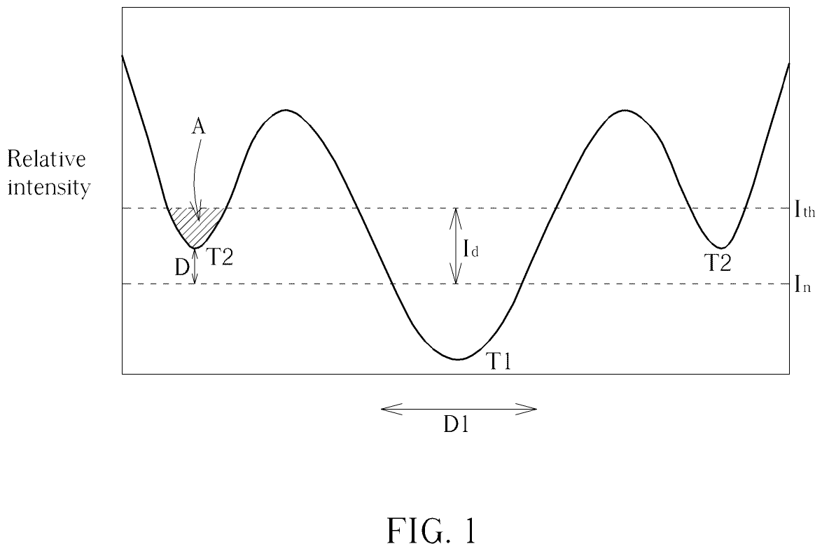

Take line pattern as an example, as shown in FIG. 1, which is an intensity graph of a photomask pattern in accordance with one embodiment of the present invention. The curve shown in FIG. 1 represents a relative intensity distribution of the pattern in a first direction D1 (ex. the width direction of a line pattern), including a primary trough T1 and two secondary troughs T2 at two sides of the adjacent primary trough T1. The primary trough T1 corresponds to the intensity of the feature pattern on the photomask (ex. opaque line pattern) and the two secondary troughs T2 are intensities generated by diffraction. The intensity of main trough T1 is lower than the intensities of the two secondary troughs T2. In some cases, the secondary trough T2 may also be generated by sub-resolution assistant feature (SRAF) or scattering bar (SB), but not limited thereto. It should be noted that the actual intensity curve may also include tertiary troughs (T3) or quaternary troughs (T4) that is further away from the primary trough T1 and has smaller amplitude. In the embodiment of the present invention, only the secondary troughs T2 closest to the primary troughs T1 and with intensity closest to that of the primary troughs T1 are used. Furthermore, the present invention is not limited to the application of intensity curves with two secondary troughs. It is also applicable to intensity curves with only one primary trough and one secondary trough adjacent to the primary trough. The aerial image simulation is provided with a nominal intensity Iₙ, representing the intensity necessary to develop the photomask pattern on a target layer. The nominal intensity Iₙ is generally determined by the radiation source used, the critical dimension of the pattern and/or the photoresist material used. As can be seen from the figure, the nominal intensity Iₙ is higher than the primary trough T1 but lower than the two secondary troughs T2, which means that the photomask pattern will be printed out during the development process under ideal circumstances, while the diffraction patterns at both sides will not. However, in actual situations, the diffraction patterns (i.e., secondary troughs T2) generated by adjacent photomask patterns may possibly produce constructive interference, causing their intensities superimposed to be lower than the nominal intensity Iₙ, so that unnecessary sidelobe patterns or SRAF patterns may be printed out in the photolithography process. This phenomenon is more likely to occur in the area with dense patterns. In other word, specific photomask patterns or pattern areas have risks of forming defective patterns in the photolithography process.

In order to deal with this problem, as shown in FIG. 1, a threshold intensity Iₜₕ is defined in the aerial image simulation. In the embodiment of present invention, the threshold intensity Iₜₕ represents the highest allowable intensity that would not expose sidelobe or SRAF patterns in the development process. It can be seen from the figure that the threshold intensity Iₜₕ is higher than the two secondary troughs T2 and the nominal intensity Iₙ, so that the threshold intensity Iₜₕ intersects with the secondary troughs T2 to define an enclosed intensity region A. There is a difference between the threshold intensity Iₜₕ and the nominal intensity Iₙ (referred hereinafter as an allowable value I_{d}). In the embodiment, the allowable value I_{d} is the nominal intensity Iₙ multiplied by a ratio, wherein the ratio is determined by the radiation source used, the critical dimension of the pattern and/or the photoresist material used, but not limited thereto. The threshold intensity Iₜₕ is the nominal intensity Iₙ plus the allowable value I_{d}.

For the determination of the risk of forming sidelobe or SRAF patterns, the conventional technology is usually based on intensity ratio. Take FIG. 1 as an example, the intensity ratio is the intensity difference D between the lowest point of secondary trough T2 and the nominal intensity Iₙ divided by the nominal intensity Iₙ. The lower the intensity ratio, the closer the secondary trough T2 to the nominal intensity Iₙ, that is, the photomask pattern is more likely to print out defective patterns. When the intensity ratio falls below a specification value, the simulation system determines that there will be a risk of forming defective patterns. The disadvantage of the aforementioned conventional approach is that it only considers the factor of the lowest intensity of the secondary trough, but does not take into account the dense/sparse degree of the photomask pattern and the waveform distribution in the first direction D1.

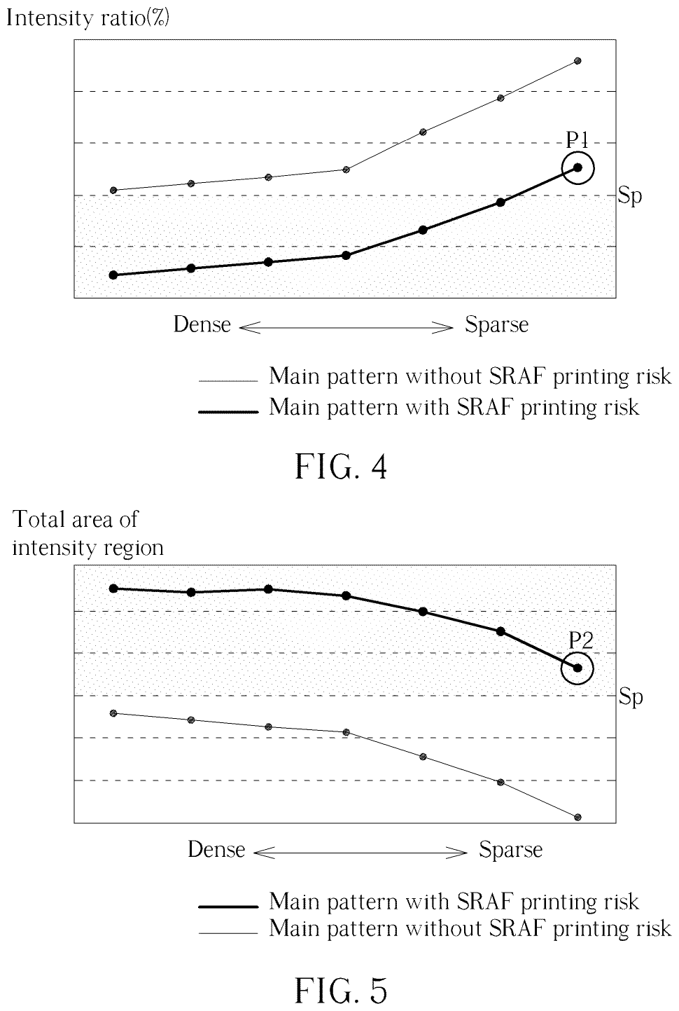

Take FIG. 4 as an example, it is a chart used in conventional skill to determine the risk of SRAF printing based on the aforementioned intensity ratio. From left to right, the density of main pattern to be formed in the photolithography process is from dense to sparse. There are two curves in the figure, which are a thin curve calculated from the intensity ratio of SRAF patterns with larger pitch and a thick curve calculated from the intensity ratio of SRAF patterns with smaller pitch, respectively. It can be seen from the figure that, when the main pattern is denser (that is, the points closer to the left), the calculated intensity ratio will be smaller. When the main pattern is sparse, the calculated intensity ratio will be larger. When the main pattern is the same (i.e., upper and lower points at the same X-axis position), the overall calculated intensity ratio will be higher if the pitch of the SRAF pattern is larger (i.e., the thin line consisting of connecting upper points). This means that the denser the main pattern and the smaller the pitch of the SRAF pattern, the more likely there will be the risk of printing out sidelobe or SRAF patterns. When the intensity ratio is lower than the specification value Sp (i.e., located in lower, shaded area), it means that defective patterns will be formed in the photolithography process. Dense patterns will produce secondary troughs with smaller intensity due to enhanced diffraction phenomenon. It can be noted that the point P1 in the figure is the intensity ratio of photomask pattern with smaller SRAF pattern pitch in an environment of sparse main pattern. The value of point P1 is higher than the specification value Sp. In terms of determination, the point P1 should be determined as being no SRAF printing risk, but the actual situation is that the photomask pattern is very likely to print out the SRAF pattern. It can also be seen from the figure that parts of the intensity ratio of the curve without the risk of SRAF printing and the curve with the risk of SRAF printing overlap in the horizontal direction, meaning that the discrimination of conventional approach is inadequate to accurately determine the risk of SRAF printing under the same specification value in some cases.

In this regard, in order to overcome the problems above, the embodiment of present invention determines whether there is a risk of SRAF printing based on the area of intensity region instead. Take FIG. 1 as an example, the defined threshold intensity Iₜₕ in the aforementioned step S2 intersects with the secondary trough T2 to define an intensity region A. When the area of intensity region A gets larger, the overall waveform of secondary trough T2 is closer to the nominal intensity Iₙ, and the risk of SRAF printing get higher. In the embodiment, when the area of intensity region A is greater than a specification value, the aerial image simulation determines that the photomask pattern has a risk of printing SRAF patterns in the photolithography process.

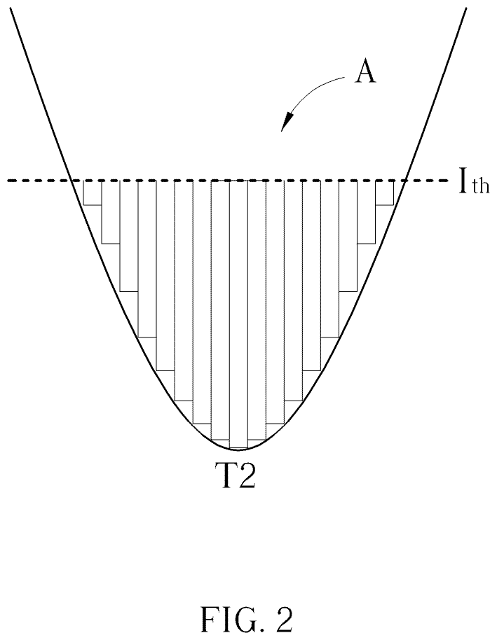

For the calculation of the area of intensity region A, in next step S3, as shown in FIG. 2, which is an enlarged graph of an intensity region A in accordance with one embodiment of the present invention. The present invention uses rectangular approximation method to obtain the area of intensity region A. The intensity region A in the figure will be first partitioned into a plurality of rectangular fragments arranged in the first direction D1. Thereafter, in step S4, the areas of these rectangular fragments are summed up to obtain a total area, which is approximate to the actual area of the intensity region A. It should be noted that in practice, the number of rectangular fragments depends on the required simulation accuracy, available computing time, photolithography process used, and/or critical size of the pattern, and different shapes of the blocks may also be used, ex. trapezoid. The rectangular approximation method can be left Riemann sum, right Riemann sum, midpoint Riemann sum, or any method that can calculate the area of an enclosed pattern, but not limited thereto.

Please refer to FIG. 5, which is a chart used to determine the risk of SRAF printing based on the aforementioned intensity region in accordance with one embodiment of the present invention. Similarly, there are two curves in the figure, which are a thin curve made from the total area of the enclosed intensity region of SRAF patterns with larger pitch and a thick curve made from the total area of the enclosed intensity region of SRAF patterns with smaller pitch, respectively. It can be seen from the figure that when the main pattern is denser (that is, the points closer to the left), the calculated total area of intensity region will be larger. When the main pattern is sparse, the calculated total area of intensity region will be smaller. Furthermore, when the main pattern is the same, the overall calculated total area of intensity region will be lower if the pitch of the SRAF pattern is larger (i.e., the thin line consisting of connecting lower points). This means that the denser the main pattern and the smaller the pitch of the SRAF pattern, the more likely there will be the risk of printing out defective patterns. In step S5, when the calculated total area of the intensity region is higher than a specification value Sp (i.e., located in upper, shaded area), it is determined that the mask pattern will print out the SRAF pattern in the photolithography process. When the calculated total area of the intensity region is lower than the specification value Sp, it is determined that the SRAF pattern will not be printed in the photolithography process. Dense patterns will produce secondary troughs with smaller intensity due to enhanced diffraction phenomenon, so as to increase the total area of the intensity region. It can be noted that the point P2 in the figure is the total area of the intensity region for a photomask pattern with smaller SRAF pattern pitch in an environment of sparse main pattern. The value of point P2 is higher than the specification value Sp, which may be determined as being highly likely to form defective features. Therefore, in comparison with the point P1 obtained by conventional technique in FIG. 4, the approach of the present invention can accurately determine the risk of defective pattern. Furthermore, it can also be seen from the figure that in the embodiment of the present invention, the total areas of the intensity regions of the curve without defect risk and the curve with defect risk does not overlap in horizontal direction, representing that the approach of present invention has excellent discrimination and can accurately determine the risk of forming defective patterns for different patterns and features, even under the same specification value.

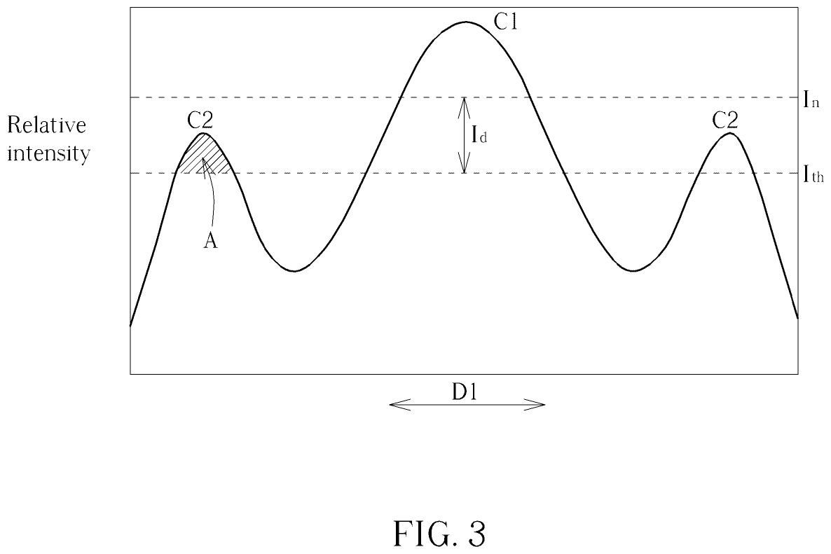

Please refer now to FIG. 3, which is an intensity graph of photomask patterns in accordance with another embodiment of the present invention. Different from the line pattern in FIG. 1, the intensity curve in this figure is generated by trench pattern on the photomask, and the waveform generated by this pattern in the aerial image is a wave crest. As shown in FIG. 3, the intensity curve includes a primary crest C1 and two secondary crests C2 at two sides of the adjacent primary crest C1. The primary crest C1 corresponds to the intensity of the feature pattern on the photomask (ex. transparent trench pattern) and the two secondary crests C2 are the intensities generated by diffraction or auxiliary pattern. The intensity of primary crest C1 is higher than the intensities of two secondary crests C2. The aerial image simulation is provided with a nominal intensity Iₙ, representing the intensity required to develop the photomask pattern on a target layer. The nominal intensity Iₙ is generally determined by the radiation source used, the critical dimension of pattern and/or the photoresist material used, but not limited thereto. As can be seen from the figure, the nominal intensity Iₙ is lower than the primary crest C1 but higher than the two secondary crests C2, which means that the photomask pattern will be printed out in the development process under ideal circumstances, while the diffraction patterns at both sides will not. Similarly, a threshold intensity Iₜₕ is defined in the aerial image simulation. In the embodiment of present invention, the threshold intensity Iₜₕ represents the lowest allowable intensity that would not expose sidelobe and SRAF patterns in the development process. It can be seen from the figure that the threshold intensity Iₜₕ is lower than the two secondary crests C2 and the nominal intensity Iₙ, so that the threshold intensity Iₜₕ intersects with the secondary crests C2 to define an enclosed intensity region A. There is a difference between the threshold intensity Iₜₕ and the nominal intensity Iₙ (referred hereinafter as an allowable value I_{d}). In the embodiment, the allowable value I_{d} is the nominal intensity Iₙ multiplied by a ratio, wherein the ratio depends on the radiation source used, the critical dimension of pattern and/or the photoresist material used, but not limited thereto. The threshold intensity Iₜₕ is the nominal intensity Iₙ minus the allowable value I_{d}. Similarly, through the rectangular approximation method shown in FIG. 2, the total area of intensity region A may be obtained. In the embodiment, when the area of intensity region A is greater than a specification value, the aerial image simulation would determine that the photomask pattern has a risk of forming defective patterns in the photolithography process, as shown in FIG. 5.

Refer back to FIG. 6. In step S5 of the method of present invention, when it is determined that the photomask pattern has a risk of sidelobe or SRAF printing, the flow would return to the layout design stage of step S1 at the beginning. The photomask patterns or areas determined as at the risk of sidelobe or SRAF printing will be modified, for example, removing corresponding scattering bars or SRAF. The steps S2-S5 is then performed again. After the photomask pattern is determined as having no defect risk, in step S6, perform a photolithography process using a photomask with the photomask pattern to transfer the photomask pattern to a photoresist on a substrate, and the photoresist pattern may be inspected in ADI stage to perform the aforementioned steps S2-S5 again to determine the existence and risk of defective patterns. If it is determined that a defective pattern is formed in step S6, the flow will return to the layout design stage of step S1 again, which the photomask patterns or areas determined as at defect risk will be modified again. If it is determined that no defective pattern is formed at this stage, the designed layout may be considered as having no problems and the layout can be tape out in step S7, which the complete layout file in GDSII format will be sent to semiconductor manufacturers for subsequent production of photomasks or semiconductor devices.

On the basis of the inspection method described in the embodiments above, the present invention also provides a computer program product with computer-executable instructions that may be executed by a computer to perform a method of inspecting the risk of printing defective pattern in photolithography process, the method includes steps of: providing a photomask pattern; generating an intensity curve of the photomask pattern in a first direction in an aerial image simulation, wherein the aerial image simulation has a threshold intensity, and the intensity curve is provided with a primary trough and two secondary troughs adjacent to the primary trough, and the primary trough is lower than the two secondary troughs, and the threshold intensity is higher than the two secondary troughs, so that the threshold intensity intersects with the secondary trough to define an intensity region; partitioning the intensity region into a plurality of rectangular fragments arranged in the first direction; adding up areas of the rectangular fragments to obtain a total area; and when the total area is less than a specification value, it is determined that the photomask pattern has no risk of printing defective pattern in the photolithography process, and when the total area is greater than the specification value, it is determined that the photomask pattern has a risk of printing defective pattern in the photolithography process.

On the basis of the inspection method described in the embodiments above, the present invention also provides a computer program product with computer-executable instructions that may be executed by a computer to perform a method of inspecting the risk of printing defective pattern in photolithography process, the method includes steps of: providing a photomask pattern; generating an intensity curve of the photomask pattern in a first direction in an aerial image simulation, wherein the aerial image simulation has a threshold intensity, and the intensity curve is provided with a primary crest and two secondary crests adjacent to the primary crest, and the primary crest is higher than the two secondary crests, and the threshold intensity is lower than the two secondary crests, so that the threshold intensity intersects with the secondary crest to define an intensity region; partitioning the intensity region into a plurality of rectangular fragments arranged in the first direction; adding up areas of the rectangular fragments to obtain a total area; and when the total area is less than a specification value, it is determined that the photomask pattern has no risk of printing defective pattern in the photolithography process, and when the total area is greater than the specification value, it is determined that the photomask pattern has a risk of printing defective pattern in the photolithography process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of inspecting a risk of printing defective pattern in photolithography process, comprising:
providing a photomask pattern;
generating an intensity curve of said photomask pattern in a first direction in an aerial image simulation, wherein said aerial image simulation has a threshold intensity, and said intensity curve is provided with a primary trough and a secondary trough adjacent to said primary trough, and said primary trough is lower than said secondary trough, and said threshold intensity is higher than said secondary trough, so that said threshold intensity intersects with said secondary trough to define an intensity region;
partitioning said intensity region into a plurality of rectangular fragments arranged in said first direction;
adding up areas of said rectangular fragments to obtain a total area; and
when said total area is less than a specification value, it is determined that said photomask pattern has no risk of printing defective pattern in said photolithography process, and when said total area is greater than said specification value, it is determined that said photomask pattern has a risk of printing defective pattern in said photolithography process.

2. The method of inspecting a risk of printing defective pattern in photolithography process of claim 1, wherein said aerial image simulation has a nominal intensity that can expose said photomask pattern in said photolithography process, and said nominal intensity is higher than said primary trough but lower than said secondary trough.

3. The method of inspecting a risk of printing defective pattern in photolithography process of claim 2, wherein said threshold intensity is equal to said nominal intensity plus an allowable value, and said allowable value is said nominal intensity multiplied by a ratio, and said ratio depends on said photolithography process.

4. The method of inspecting a risk of printing defective pattern in photolithography process of claim 1, wherein after it is determined that said photomask pattern has no risk of printing defective pattern in said photolithography process, further comprising:
providing a photomask having said photomask pattern;
using said photomask to perform said photolithography process to form said photomask pattern in a photoresist; and
determining if said photomask pattern in said photoresist contains defective pattern.

5. A method of inspecting a risk of printing defective pattern in photolithography process, comprising:
providing a photomask pattern;
generating an intensity curve of said photomask pattern in a first direction in an aerial image simulation, wherein said aerial image simulation has a threshold intensity, and said intensity curve is provided with a primary crest and a secondary crest adjacent to said primary crest, and said primary crest is higher than said secondary crest, and said threshold intensity is lower than said secondary crest, so that said threshold intensity intersects with said secondary crest to define an intensity region;
partitioning said intensity region into a plurality of rectangular fragments arranged in said first direction;
adding up areas of said rectangular fragments to obtain a total area; and
when said total area is less than a specification value, it is determined that said photomask pattern has no risk of printing defective pattern in said photolithography process, and when said total area is greater than said specification value, it is determined that said photomask pattern has a risk of printing defective pattern in said photolithography process.

6. The method of inspecting a risk of printing defective pattern in photolithography process of claim 5, wherein said aerial image simulation has a nominal intensity that can expose said photomask pattern in said photolithography process, and said nominal intensity is lower than said primary crest but higher than said secondary crest.

7. The method of inspecting a risk of printing defective pattern in photolithography process of claim 6, wherein said threshold intensity is equal to said nominal intensity minus an allowable value, and said allowable value is said nominal intensity multiplied by a ratio, and said ratio depends on said photolithography process.

8. The method of inspecting a risk of printing defective pattern in photolithography process of claim 5, wherein after it is determined that said photomask pattern has no risk of printing defective pattern in said photolithography process, further comprising:
providing a photomask having said photomask pattern;
using said photomask to perform said photolithography process to form said photomask pattern in a photoresist; and
determining if said photomask pattern in said photoresist contains defective pattern.

9. A computer program product with computer-executable instructions that are executed by a computer to perform a method of inspecting a risk of printing defective pattern in photolithography process, said method comprises:
providing a photomask pattern;
generating an intensity curve of said photomask pattern in a first direction in an aerial image simulation, wherein said aerial image simulation has a threshold intensity, and said intensity curve is provided with a primary trough and a secondary trough adjacent to said primary trough, and said primary trough is lower than said secondary trough, and said threshold intensity is higher than said secondary trough, so that said threshold intensity intersects with said secondary trough to define an intensity region;
partitioning said intensity region into a plurality of rectangular fragments arranged in said first direction;
adding up areas of said rectangular fragments to obtain a total area; and
when said total area is less than a specification value, it is determined that said photomask pattern has no risk of printing defective pattern in said photolithography process, and when said total area is greater than said specification value, it is determined that said photomask pattern has a risk of printing defective pattern in said photolithography process.

10. The computer program product with computer-executable instructions of claim 9, wherein said aerial image simulation has a nominal intensity that can expose said photomask pattern in said photolithography process, and said nominal intensity is higher than said primary trough but lower than said secondary trough.

11. The computer program product with computer-executable instructions of claim 10, wherein said threshold intensity is equal to said nominal intensity plus an allowable value, and said allowable value is said nominal intensity multiplied by a ratio, and said ratio depends on said photolithography process.

12. The computer program product with computer-executable instructions of claim 9, wherein after it is determined that said photomask pattern has no risk of printing defective pattern in said photolithography process, further comprising:
providing a photomask having said photomask pattern;
using said photomask to perform said photolithography process to form said photomask pattern in a photoresist; and
determining if said photomask pattern in said photoresist contains defective pattern.

13. A computer program product with computer-executable instructions that are executed by a computer to perform a method of inspecting a risk of printing defective pattern in photolithography process, said method comprises:
providing a photomask pattern;
generating an intensity curve of said photomask pattern in a first direction in an aerial image simulation, wherein said aerial image simulation has a threshold intensity, and said intensity curve is provided with a primary crest and a secondary crest adjacent to said primary crest, and said primary crest is higher than said secondary crest, and said threshold intensity is lower than said secondary crest, so that said threshold intensity intersects with said secondary crest to define an intensity region;
partitioning said intensity region into a plurality of rectangular fragments arranged in said first direction;
adding up areas of said rectangular fragments to obtain a total area; and
when said total area is less than a specification value, it is determined that said photomask pattern has no risk of printing defective pattern in said photolithography process, and when said total area is greater than said specification value, it is determined that said photomask pattern has a risk of printing defective pattern in said photolithography process.

14. The computer program product with computer-executable instructions of claim 13, wherein said aerial image simulation has a nominal intensity that can expose said photomask pattern in said photolithography process, and said nominal intensity is lower than said primary crest but higher than said secondary crest.

15. The computer program product with computer-executable instructions of claim 14, wherein said threshold intensity is equal to said nominal intensity minus an allowable value, and said allowable value is said nominal intensity multiplied by a ratio, and said ratio depends on said photolithography process.

16. The computer program product with computer-executable instructions of claim 13, wherein after it is determined that said photomask pattern has no risk of printing defective pattern in said photolithography process, further comprising:
providing a photomask having said photomask pattern;
using said photomask to perform said photolithography process to form said photomask pattern in a photoresist; and
determining if said photomask pattern in said photoresist contains defective pattern.
